(19) United States
(12) Patent Application Publication
(10) Pub. No.: US 2006/0040136 A1
(43) Pub. Date: Feb. 23, 2006

(54) Method of making an optical device

(75) Inventors: Zugang Liu, Oxford (GB); Natasha Conway, Cambridge (GB); Ilaria Grizzi, Cambridge (GB)

Correspondence Address: MARSHALL, GERSTEIN & BORUN LLP, 233 S. WACKER DRIVE, SUITE 6300, SEARS TOWER, CHICAGO, IL, 60606, US

(73) Assignee: CDT OXFORD LTD., Cambridgeshire (GB)

(21) Appl. No.: 11/202,130

(22) Filed: Aug. 11, 2005

(30) Foreign Application Priority Data
Aug. 12, 2004 (GB) 0418019.6

(51) Int. Cl. H05B 33/12; H05B 33/10; B05D 3/00

(52) U.S. Cl. 428/690; 428/917; 313/504; 313/506; 427/66

(57) ABSTRACT

A method of forming a an emissive layer of an optical device includes the steps of depositing a phosphorescent material to form a deposited layer, and annealing the deposited layer to form an emissive layer. A method of manufacturing an optical device, an emissive layer of an optical device, and an optical device containing such a layer are also disclosed.

### BACKGROUND OF THE INVENTION

1. Field of the Invention

The invention relates to a method of making a layer of an optical device. In articular, the invention relates to a method of making a light emissive layer of an optical device, the layer being a phosphorescent material.

2. Related Technology

Solution-processable, film-forming materials are expected to be used in optical devices, such as light emitting display devices, for the next generation of information technology based consumer products because solution processing techniques, such as inkjet printing, offer the possibility of large area, high resolution devices that may be manufactured at low cost. Over the last decade much effort has been devoted to the improvement of the emission lifetime and efficiency of organic light emitting devices (OLEDs) either by developing new materials or new device structures.

Classes of solution processable organic light emitting materials include: alkyl- or alkoxy substituted poly(arylene vinylenes) such as 2-methoxy-5-(2-ethyl-hexyloxy)-1,4-phenylene vinylene (MEH-PPV); polyarylenes such as alkyl- or alkoxy-substituted polyfluorenes, poly(indenofluorenes), polythiophenes and polyphenylenes; and the class of materials known as dendrimers as disclosed in WO 99/21935.

The physical properties of a charge transporting or electroluminescent layer such as its morphology, or phase separation in the case of a blend, will depend in part on its deposition conditions. It has been postulated that modification of these properties by heat treatment of the layer may in turn affect device performance. For example, polymer chains may relax and take on a new conformation at temperatures above the glass transition temperature (Tg) of that polymer. Heat treatment of fluorescent OLEDs is disclosed in the following:

J. Appl. Phys. 91(3), 2002, 1595-1600 discloses heat treatment of MEH-PPV prior to deposition of the cathode (hereinafter referred to as pre-cathode heating). Annealing below Tg is reported to improve electroluminescent efficiency of a single layer device; annealing above Tg is reported to improve hole injection efficiency.

Synth. Met. 117 (2001) 249-251 discloses heat treatment of MEH-PPV above the Tg of the polymer either before or after deposition of the cathode. The most significant improvements are reported to be a fall in operating voltage and increase in quantum efficiency upon heat treatment following cathode deposition (hereinafter referred to as post-cathode heating).

Adv. Mater. 2000, 12(11), 801-804 discloses pre-cathode heating of MEH-PPV above or below Tg and/or post-cathode heating above Tg. The most efficient device is reported to be that undergoing post-cathode heating only. Similarly, Appl. Phys. Lett. 77(21), 2000, 3334-3336 discloses pre-cathode heating below Tg and post-cathode heating above Tg, however the pre-cathode heating in this case is thought to be only for the purpose of removing residual solvent.

Appl. Phys. Lett. 80(3), 2002, 392-394 discloses post-cathode heating of a polythiophene derivative above or below Tg. Device performance improvements are reported at temperatures above and below Tg.

Appl. Phys. Lett. 81(4), 2002, 634-636 discloses post-cathode heating of a copolyfluorene. Improved device performance is reported at temperatures below Tg.

JP 2000-311784 discloses heat treatment of a small molecule below Tg either after or at the time of small molecule film formation.

Improvements in the efficiency of photovoltaic devices by heat treatment are disclosed in J. Appl. Phys. 88(12), 2000, 7120-7123 and in Solar Energy Materials and Solar Cells, 61, 2000, 53-61.

WO 2004/034749 discloses improved device performance resulting from heat treatment of a polyfluorene below Tg both before and after cathode deposition.

J. Phys. D: Appl. Phys. 35 (2002) 520-523 reports a study on the effects of electrical annealing of the organic emissive (fluorescent) layer on the performance of OLEDs. The organic emissive layer in the study is a conjugated dendrimer doped with 2-(4-biphenylyl)-5-(4-tert-butylphenyl)-1,3,4-oxadiazole.

Chem. Mater. 2002, 14, 463-470 reports the synthesis and characterisation of a series of spiro-configured terfluorenes as fluorescent blue light emitters. The effect of thermal annealing the terflourenes is discussed.

Also, U.S. 2003/0054197 discloses annealing two adjacent organic layers in an OLED, which it is said is believed to allow for some diffusion at the interface, thus improving the OLED performance. In the Examples, the layers are deposited by vacuum deposition and the emissive layer is deposited after annealing i.e. the emissive layer is not annealed.

In OLEDs, electrons and holes are injected from opposite electrodes and are combined to form two types of excitons; spin-symmetric triplets and spin-antisymmetric singlets in a theoretical ratio of 3:1. Radiative decay from the singlets is fast (fluorescence), but from the triplets (phosphorescence) it is formally forbidden by the requirement of the spin conservation. Therefore, spin statistics dictate that up to 75% of excitons are triplet excitons which undergo non-radiative decay, i.e. quantum efficiency may be as low as 25% for fluorescent OLEDs—see, for example, Chem. Phys. Lett., 1993, 210, 61, Nature (London), 2001, 409, 494, Synth. Met., 2002, 125, 55 and references therein.

Initially spurred on by this understanding the idea of transferring both singlets and triplets to a phosphorescent dopant was conceived. Such a phosphor ideally is able to accept both singlet and triplet excitons from the organic material and generate luminescence, particularly electroluminescence from both.

Recently, many have studied the incorporation by blending of small molecule phosphorescent metal complexes into an organic semiconductive layer. Good results have been achieved for OLEDs based on blends incorporating a phosphorescent metal complex dopant and a small molecule or a non-conjugated polymer host such as polyvinylcarbazole. Conjugated polymers have also been disclosed as hosts, for example a blend of Eu(dnm)₃phen in CN-PPP with a quantum efficiency of 1.1%. [Adv. Mater., 1999, 11, 1349.]. Similarly, Phys. Rev. B 2001, 63, 235206 discloses poly(9,9-dioctylfluorene) doped with 2,3,7,8,12,13,17,18-octaethyl-21H,23H-porphyrin platinum (II).

As described in WO 02/066552, small molecule metal complexes have in the past been designed to be volatile so that layers can be deposited by thermal evaporation. However, in optical device manufacture, solution processing would be preferable to evaporation due to the lower cost of solution processing as well as the possibility of deposition over large substrates. In particular, deposition of electroluminescent materials by inkjet printing onto flexible substrates in a roll-to-roll manufacturing process offers the possibility of cheap, large area displays. Unfortunately, generally, small molecule metal complexes do not form good films when deposited by solution processing even in those cases where the complex is soluble in a solvent. For example, formation of a film of uniform thickness by inkjet printing, in particular an individual pixel or subpixel, is dependent on numerous parameters of the inkjet formulation including viscosity, contact angle with the substrate and boiling point of the solvent.

WO 02/066552 represents a development in this field and relates to dendrimers with metal ions as part of the core. Dendrimers are highly branched macromolecules in which branched dendrons (also called dendrites) are attached to a core. It is said that the properties of dendrimers make them ideal for solution processing and allow the incorporation of metal complex chromophores. In the devices described in WO 02/066552, during device manufacture, the dendrimer film is deposited by spin coating and then calcium and aluminium are deposited over the top by vacuum deposition to form the cathode and to complete device manufacture.

WO 03/091355 also represents an improvement in this field and discloses phosphorescent materials which comprise a polymer or oligomer and an organometallic, which is covalently bound to the polymer or oligomer. It is said that an advantage of these materials is that they are solution processable. In making the OLED devices disclosed in WO 03/091355, the emitting layer is spin coated from a solution and then calcium and aluminium are vacuum deposited over the top to form the cathode and to complete device manufacture.

Although WO 02/066552 and WO 03/091355 represent advancements in the field of phosphorescent materials for use in optical devices such as OLEDs, there remains a need for further improvements to optimise the efficiency and lifetime of phosphorescent devices in order to compete in the marketplace (by “lifetime” is meant the time taken for brightness of a phosphorescent device to decay by 50% from a starting brightness when driven at constant current).

### DESCRIPTION OF THE INVENTION

Accordingly, it is an aim of the invention to at least partially address this need by providing an improved method for making a light emissive layer of an optical device, the layer comprising a phosphorescent material.

The invention therefore provides, in a first aspect, a method of forming an emissive layer of an optical device, said method comprising the steps of:
(i) depositing a phosphorescent material to form a deposited layer; and
(ii) annealing the deposited layer.

In the method according to the first aspect, annealing the deposited layer has been found to lead to an unexpectedly large increase in the lifetime of the optical device, thus providing significant advantages over the phosphorescent devices described in WO 02/066552 and WO 03/091355 and elsewhere.

Annealing (akin to baking) is the process by which a substance is heated and then cooled in a controlled manner to relieve stresses. In general, ordered structures are produced by annealing.

Without wishing to be bound by theory, it is suggested that annealing increases device lifetime by at least partially removing residual solvent trapped within the phosphorescent material film, which can cause device degradation. Moreover, annealing of a system comprising a blend of a host and a dopant material may result in better mixing between the two components, leading to better charge transfer from the host material to the emissive dopant. Finally, charge transfer between the hole transport layer (if present) and the emissive layer may be improved by the process of annealing. Annealing of the blended film (host dopant) layer may result in an accelerated modification to the film morphology, which may be occurring slowly at room temperature in driven or non driven devices. These changes could be the cause of improved lifetime. Such modifications could result in improved contact between host and dopant phase domains and improved interfacial layer mixing (i.e. improved contact between emissive layer and other layers HTL for example). These improvements may be caused by changes in morphology.

In the method according to the first aspect, preferably, the phosphorescent material is deposited in step (i) by depositing a solution containing the phosphorescent material by a solution processing technique. Solution processing of the phosphorescent material is preferred for the reasons set out above. Therefore, it is preferred that the phosphorescent material is soluble. Preferred solvents include toluene, THF, water and alcoholic solvents such as methanol.

A preferred solution processing technique is ink jet printing.

In the method according to the first aspect, annealing may be carried out directly after deposition in step (i). Alternatively, further layers, such as an electron transport layer or the cathode, may be deposited over the deposited layer formed in step (i) before annealing.

In step (i), preferably, the phosphorescent material is deposited directly onto a charge transport layer. More preferably, the charge transport layer comprises a hole transport layer.

Thermal annealing is preferred. The annealing temperature and time should be sufficient to drive off residual solvent but should not result in large scale crystallisation of the amorphous film. The annealing temperature is preferably in the range 50-200° C., more preferably 80-150° C. The annealing time for this temperature range is preferably in the range of one minute to one hour, more preferably 5-20 minutes. Higher temperatures may be used in combination with shorter annealing times.

Turning to the phosphorescent material, preferably the phosphorescent material is part of a host material-dopant system, where the dopant comprises the phosphorescent material. In one embodiment, the host material and the phosphorescent material are present as separate materials, which are blended together. In another embodiment, the host material and the phosphorescent material are components of the same compound. In this embodiment, preferably, the compound is a polymer, so that a polymer comprises the host material and the phosphorescent material. The phosphorescent material may be present as a repeat unit in the polymer.

Preferably, the phosphorescent material comprises a metal complex. In the metal complex, the metal ion typically is a metal cation. It is to be understood that the term “metal ion” or “metal cation”, as used herein, describes the charge state the metal would have without any ligands attached (the oxidation state).

Preferred phosphorescent metal complexes comprise optionally substituted complexes of formula (I):
ML¹_{q}L²ᵣL³ₛ (I)
wherein M is a metal; each of L¹, L² and L³ is a coordinating group; q is an integer; r and s are each independently 0 or an integer; and the sum of (a. q)+(b. r)+(c.s) is equal to the number of coordination sites available on M, wherein a is the number of coordination sites on L¹, b is the number of coordination sites on L² and c is the number of coordination sites on L³.

L¹, L² and L³ may independently be a mono- or polydentate ligand.

Where q, r or s is greater than 1 then the plurality of groups L¹, L² or L³ respectively may be linked to form a polydentate ligand.

Additionally, or alternatively, one or more of L¹, L² and L³ may be linked to form a polydentate ligand.

Heavy metals M enable phosphorescence by inducing strong spin-orbit coupling to allow rapid intersystem crossing and emission from triplet states. Suitable heavy metals M include:
lanthanide metals such as cerium, samarium, europium, terbium, dysprosium, thulium, erbium and neodymium; and
heavy d-block metals, in particular ruthenium, rhodium, palladium, rhenium, osmium, iridium, platinum and gold.

Suitable coordinating groups for the f-block metals include oxygen or nitrogen donor systems such as carboxylic acids, 1,3-diketonates, hydroxy carboxylic acids, Schiff bases including acyl phenols and iminoacyl groups. As is known, luminescent lanthanide metal complexes require sensitizing group(s) which have the triplet excited energy level higher than the first excited state of the metal ion. Emission is from an f-f transition of the metal and so the emission colour is determined by the choice of the metal. The sharp emission is generally narrow, resulting in a pure colour emission useful for display applications.

The d-block metals form organometallic complexes with carbon or nitrogen donors such as porphyrin or bidentate ligands of formula (VI): 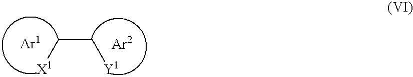
wherein Ar¹ and Ar² may be the same or different and are independently selected from optionally substituted aryl or heteroaryl; X¹ and Y¹ may be the same or different and are independently selected from carbon or nitrogen; and Ar¹ and Ar² may be fused together. Ligands wherein X¹ is carbon and Y¹ is nitrogen are particularly preferred.

Examples of bidentate ligands are illustrated below:

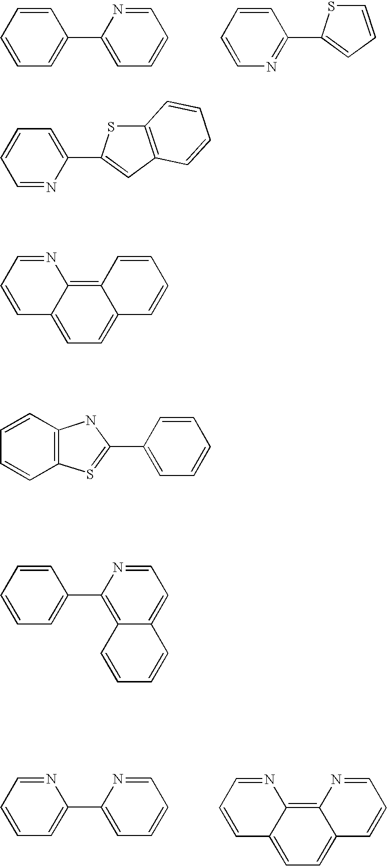

Examples of suitable monodentate ligands include carbonyl, nitrile, isonitrile and alkylisonitriles, thiocyanide, alkylphosphines and arylphosphines, in particular triphenylphosphine, halides, in particular chloride or bromide, heterocyclic compounds such as pyridine and substituted pyridines and alkynes. Preferred monodentate ligands include carbonyl, nitrile, isonitriles, triarylphosphines and halides.

For iridium complexes, the part of the ligands attached to the metal is preferably a nitrogen-containing heteroaryl, for example pyridine, attached to a (hetero)aryl where aryl can be a fused ring system, for example substituted or unsubstituted phenyl or benzothiophene.

Rhenium complexes preferably have formula ReL¹L²₃L³ wherein L¹ is a bidentate ligand and L² and L³ are the same or different and represent monodentate ligands.

Each of Ar¹ and Ar² may carry one or more substituents. Particularly preferred substituents include fluorine or trifluoromethyl which may be used to blue-shift the emission of the complex as disclosed in WO 02/45466, WO 02/44189, U.S. 2002-117662 and U.S. 2002-182441; alkyl or alkoxy groups as disclosed in JP 2002-324679; carbazole which may be used to assist hole transport to the complex when used as an emissive material as disclosed in WO 02/81448; bromine, chlorine or iodine which can serve to functionalise the ligand for attachment of further groups as disclosed in WO 02/68435 and EP 1245659; and dendrons which may be used to obtain or enhance solution processability of the metal complex as disclosed in WO 02/66552.

Other ligands suitable for use with d-block elements include diketonates, in particular acetylacetonate (acac); triarylphosphines and pyridine, each of which may be substituted.

In a first embodiment of the method according to the first aspect, the metal complex comprises a dendrimer with a metal as part of its core. Dendrimers are highly branched macromolecules in which branched dendrons (also called dendrites) are attached to a core.

In the first embodiment, preferably, the dendrimer is blended with a host material. Preferably, the host material is at least 99% pure, more preferably at least 99.8% pure.

The dendrimer may contain one or more at least partially conjugated organic dendrons.

A dendrimer according the first embodiment typically comprises the formula II:
CORE−[DENDRITE]ₙ II
in which CORE represents a metal cation or a group containing a metal ion, n represents an integer of 1 or more, each DENDRITE, which may be the same or different represents an inherently at least partially conjugated dendritic structure comprising aryl and/or heteroaryl groups or nitrogen and, optionally, vinyl or acetylenyl groups connected via sp or sp hybridised carbon atoms of said (hetero)aryl vinyl and acetylenyl groups or via single bonds between N and (hetero)aryl groups, CORE terminating in the single bond which is connected to an sp hybridised (ring) carbon atom of the first (hetero)aryl group or single bond to nitrogen to which more than one at least partly conjugated dendritic branch is attached, said ring carbon or nitrogen atom forming part of said DENDRITE.

Suitable branching points include aryl and heteroaryl, which can be fused, aromatic ring systems and N. The links between branching points include bonding combinations such as aryl-aryl, aryl-vinyl-aryl, aryl-acetylenyl-aryl, aryl-aryl′-aryl (where aryl′ may be different from aryl), N-aryl and N-aryl′-N. An individual dendron may contain one or more of each type of branching point. Moreover, in the case of the aryl-vinyl-aryl and aryl-acetylenyl-aryl linkages within the dendron there may be one or more aryl-vinyl or aryl-acetylenyl link between the branching points. Indeed there may be more than one vinyl or acetylenyl or aryl moiety between two aryl groups but preferably no more than three.

The dendrimer according to the first embodiment may comprise the formula III:
CORE−[DENDRITE¹]ₙ [DENDRITE²]ₘ III

In which CORE represents a metal ion or a group containing a metal ion, n and m, which may be the same or different, each represent an integer of at least 1, each DENDRITE¹, which may be the same or different when n is greater than 1, and each DENDRITE², which may be the same or different when m is greater than 1, represent dendritic structures, at least one of said structures being fully conjugated and comprising aryl and/or heteroaryl groups or nitrogen and, optionally, vinyl and/or acetylenyl groups, connected via-sp² or sp hybridized carbon atoms of said (hetero)aryl, vinyl and acetylenyl groups or via single bonds between N and (hetero)aryl groups, and the branching points and/or the links between the branching points in DENDRITE¹ being different from those in DENDRTITE², CORE terminating in the single bond which is connected to a sp² hybridized (ring) carbon atom of the first (hetero)aryl groups or single bond to nitrogen to which more than one conjugated dendritic branch is attached, said ring carbon atom or nitrogen forming part of said fully conjugated DENDRITE¹ or DENDRITE² and CORE terminating at the single bond to the first branching point for the other of said DENDRITE¹ or DENDRITE², at least one of the CORE, DENDRITE¹ and DENDRITE² being phosphorescent.

For the purposes of the invention, “conjugated” dendrons (dendrites) indicate that they are made up of alternating double and single bonds, apart from the surface groups. However this does not mean that the pi system is fully delocalised. The delocalisation of the pi system is dependent on the regiochemistry of the attachments.

In a conjugated dendron any branching nitrogen will be attached to 3 aryl groups.

Suitable surface groups for the dendrimers include branched and unbranched alkyl, especially t-butyl, branched and unbranched alkoxy, for example 2-ethylhexyloxy, hydroxy, alkylsilane, carboxy, carbalkoxy, and vinyl. A more comprehensive list includes a further-reactable alkene, (meth)acrylate, sulphur-containing, or silicon-containing group; a sulphonyl group; polyether group; a C1-to-C15 alkyl (preferably t-butyl) group; an amine group; a mono-, di- or tri-C1-to-C15 alkyl amine group; a —COOR group wherein R is hydrogen or C1-to-C15 alkyl; an —OR group wherein R is hydrogen, aryl, or C1-to-C15 alkyl or alkenyl; an —O2SR group wherein R is C1-to-C15 alkyl or alkenyl; an —SR group wherein R is aryl, or C1-to-C15 alkyl or alkenyl; an —SiR3 group wherein the R groups are the same or different and are hydrogen, C1-to-C15 alkyl or alkenyl, or an —SR′ group (R′ is aryl or C1-to-C15 alkyl or alkenyl), aryl, or heteroaryl. Typically t-butyl and alkoxy groups are used. Different surface groups may be present on different dendrons or different distal groups of a dendron.

The dendrimers preferably are solution processable. Therefore, desirably, the surface groups are selected so the dendrimers are soluble in solvents suitable for solution processing. The surface groups and dendrites can be varied so the dendrimers are soluble in solvents, such as toluene, THF, water and alcoholic solvents such as methanol, suitable for the solution processing technique of choice. Preferable surface groups for this purpose are alkyl and alkoxy groups. Typically t-butyl and alkoxy groups have been used.

In addition, the choice of dendron and/or surface group can allow the formation of blends with dendrimers (organic or organometallic), polymer or molecular compounds.

The surface groups can be chosen such that the dendrimer can be photopatterned. For example a cross-linkable group is present which can be cross-linked upon irradiation or by chemical reaction. Alternatively the surface group comprises a protecting group which can be removed to leave a group which can be cross-linked.

The aryl groups within the dendrons can be typically benzene, napthalene, biphenyl (in which case an aryl group is present in the link between adjacent branching points) anthracene, fluorene, pyridine, oxadiazole, triazole, triazine, thiophene. These groups may optionally be substituted, typically by C1 to C15 alkyl or alkoxy groups. The aryl groups at the branching points are preferably benzene rings, preferably coupled at ring, positions 1, 3 and 5, pyridyl or triazinyl rings.

It is possible to control the electron affinity of the dendrimers by the addition to the chromophores of electron-withdrawing groups, where appropriate, for example cyano and sulfone which are strongly electron-withdrawing and optically transparent in the spectral region of interest here. Further details of this and other modifications of the dendrimers can be found in WO99/21935, the entire disclosure of which is incorporated herein by reference.

One or more of the dendrons attached to the core (provided that at least one dendron is a specified conjugated dendron) can be unconjugated. Typically such dendrons include ether-type aryl dendrons, for example where benzene rings are connected via a methyleneoxy link.

Also, when there is more than one dendron, the dendrons can be of the same or different generation (generation level is determined by the number of sets of branching points). It may be advantageous for at least one dendron to be of the second, or higher, generation to provide the required solution processing properties.

Preferably, CORE represents a complex of formula (I) above in which case at least one of L¹, L² and L³ is a coordinating group attached to a single bond in which CORE terminates. The single bond in the, or each, L¹, L² and/or L³ moiety, being a bond in which CORE terminates, connects to a dendron. It is desirable that the number of dendrons is sufficient to provide the required solution processing. Preferably there are at least two dendrons in a dendrimer. The said two or more dendrons typically have the structures represented by DENDRITE, DENDRITE¹ and/or DENDRITE² as defined in formulae (II) and (III) above. One or more of L¹, L² and/or L³ may be neutral or charged chelated ligands which are not attached to dendrons and which serve to fulfil the coordination requirements of the metal cation.

The dendrimer more preferably has a general formula IV: 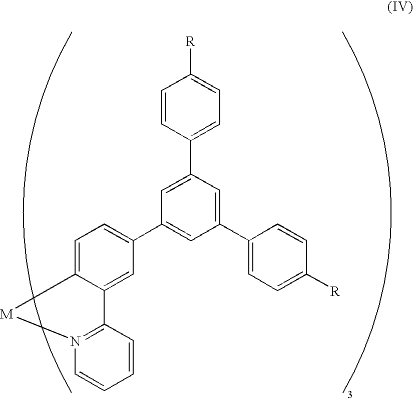
where M represents a metal and each R independently is a solubilising surface group such as an alkyl or alkoxy group as discussed above.

A dendrimer of particular interest has formula V: 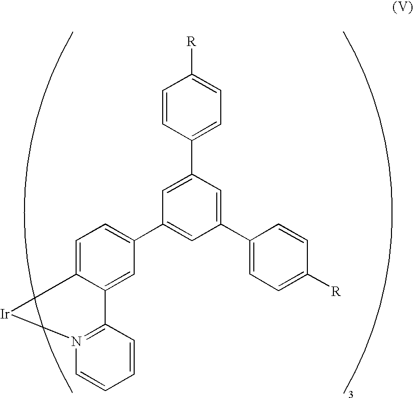
where R is as defined above for general formula IV.

The preparation of this dendrimer is described in Lo et al, Adv Mater, 2002, 14, 13-14, 975-979.

In a second embodiment of the method according to the first aspect, the metal complex comprises a repeat unit within a polymer.

The metal complex may be a repeat unit in the polymer main chain or may be pendant from the polymer main chain.

The polymer backbone may be conjugated or non-conjugated, in which case the metal complex may be conjugated with the polymer backbone, in particular as a repeat unit within the polymer backbone, or may be spaced from the conjugated backbone, for example by way of a spacer group linking the polymer backbone to the metal complex.

Preferably, the polymer is solution processable.

The polymer may provide the function of charge transport as well as emission, in which case a separate charge transporting host material may be unnecessary in the electroluminescent layer.

Alternatively, the polymer may merely serve to solubilize the metal complex in which case the electroluminescent layer preferably further comprises a charge transporting host material.

It will be understood that the method as defined in relation to the first aspect of the invention will be used in a method of manufacturing an optical device. Thus, a second aspect of the invention provides the use of the method defined in relation to the first aspect in a method of manufacturing an optical device.

A third aspect of the invention provides a layer of an optical device obtainable by the method defined in relation to the first aspect.

A fourth aspect of the invention provides an optical device obtainable by the method defined in relation to the second aspect. The optical device therefore is a phosphorescent device.

In the third and fourth aspects, the optical device preferably comprises an organic light-emitting device (OLED). More preferably, the optical device comprises an electroluminescent device. A suitable device structure is shown in FIG. 1.

The optical device according to the fourth aspect typically comprises:
an anode;
a cathode;
an emissive layer located between the anode and the cathode; and
optionally one or more further layers located between the anode and the cathode.

The emissive layer comprises an annealed phosphorescent material i.e. a phosphorescent material that has been deposited and then annealed during device manufacture. The phosphorescent material may be as defined anywhere above.

A light emitting device (LED) according to the invention desirably comprises a substrate, an anode (preferably of indium tin oxide), an optional layer of organic hole injection material, an emissive layer, an optional layer of organic electron injection material and a cathode.

The emissive layer comprises an organic host and a phosphorescent emitter. The organic host acts to transport charge to the phosphorescent emitter and also acts as a triplet source whereby triplet excited states are formed in the organic host and then transferred to the phosphorescent emitter where they decay with the emission of light. Prior art organic hosts used in phosphorescent light emitting systems include carbazoles such as polyvinylcarbazole, known as PVK; 4,4′-bis(carbazol-9-yl)biphenyl), known as CBP, N,N-dicarbazolyl-3,5-benzene, known as mCP, diphenyldi(o-tolyl) silane or p-bis(triphenylsilyly)benzene, described in Holmes et al. (Appl. Phys. Lett., 83, no. 18, 2003, 3818); and (4,4′,4″-tris(carbazol-9-yl)triphenylamine), known as TCTA, described in Ikai et al. (Appl. Phys. Lett., 79 no. 2, 2001, 156). Triarylamines may also be used as host materials, in particular tris-4-(N-3-methylphenyl-N-phenyl)phenylamine, known as MTDATA. Where the phosphorescent emitter and the host are both soluble they may be deposited as a blend by solution processing techniques such as spin-coating, doctor blade coating, screen printing or ink-jet printing. Where the phosphorescent emitter and the host are insoluble and volatile they may be deposited by vacuum deposition. The phosphorescent emitter and host are preferably present in a blend comprising 5 to 50 mol % of phosphorescent emitter, preferably 10-30 mol % of phosphorescent emitter.

Preferably, only one emissive layer is present however at least one further emissive layer (fluorescent or phosphorescent) may be provided such that the resulting colour of light emitted by the devices derives from a combination of the emissions from the plurality of emissive layers as described in U.S. Pat. No. 5,807,627.

Usually, the anode is provided on a substrate in the LED according to the present invention. Optical devices tend to be sensitive to moisture and oxygen. Accordingly, the substrate preferably has good barrier properties for prevention of ingress of moisture and oxygen into the device. The substrate is commonly glass, however alternative substrates may be used, in particular where flexibility of the device is desirable. For example, the substrate may comprise a plastic as in U.S. Pat. No. 6,268,695 which discloses a substrate of alternating plastic and barrier layers or a laminate of thin glass and plastic as disclosed in EP 0949850.

Although not essential, the presence of a hole transporting layer between the anode and the light emissive layer is desirable as it assists hole injection from the anode into the emissive layer. Examples of organic hole injection materials include PEDT:PSS as disclosed in EP 0901176 and EP 0947123, or polyaniline as disclosed in U.S. Pat. No. 5,723,873 and U.S. Pat. No. 5,798,170. PEDT:PSS is both hole transporting and insoluble in common organic solvents so that the emitting layer can be solution-deposited on top. Other hole transporting materials include, TPD (N,N′-diphenyl-N,N′-bis(3-methylphenyl)[1,1′-biphenyl]-4,4′-diamine), NPD (4,4′-bis[N-naphthyl)-N-phenyl-amino]biphenyl) and MTDATA.

In the case of solution processed devices, a hole transporting monomer may be deposited from solution and cross-linked by thermal or UV treatment to form an insoluble hole transport layer which is stable to the solution deposition of further layers such as the emissive layer. A hole transport layer which has been shown to be particularly advantageous in this respect comprises polymerised divinyl-TPD.

The cathode is selected so that electrons are efficiently injected into the device and as such may comprise a single conductive material such as a layer of aluminium. Alternatively, it may comprise a plurality of metals, for example a bilayer of calcium with a capping layer of aluminium as disclosed in WO 98/10621. A thin layer of dielectric material such as lithium fluoride optionally may be provided between the light emissive layer and the cathode to assist electron injection as disclosed in, for example, WO 00/48258. Preferably, the cathode comprises a metal having a workfunction less than 3.5 eV, more preferably less than 3 eV, in combination with a capping layer such as aluminium and/or a thin dielectric layer such as lithium fluoride.

The device is preferably encapsulated with an encapsulant to prevent ingress of moisture and oxygen. Suitable encapsulants include a sheet of glass, films having suitable barrier properties such as alternating stacks of polymer and dielectric as disclosed in, for example, WO 01/81649 or an airtight container, optionally with a desiccant, as disclosed in, for example, WO 01/19142.

In a practical device, at least one of the electrodes is semi-transparent in order that light may be emitted. Where the anode is transparent, it typically comprises indium tin oxide. Examples of transparent cathodes are disclosed in, for example, GB 2348316.

Optionally, the device further may have an electron transport layer located between the cathode and the emissive layer. Suitable materials for an electron transporting layer include 2,9-dimethyl-4,7-diphenyl-1,10-phenanthroline (BCP), 1,3,5-tris(2-N-phenylbenzimidazolyl)benzene (TPBI) and 2-biphenyl-5(4′-t-butylphenyl)oxadiazole (PBD).

In order to further optimize the device lifetime, it is preferable that the electron transport material and hole transport material, when present, are as pure as possible, preferably more than 99% pure.

Also, the dendrimer should be as pure as possible, preferably at least 90% pure, more preferably more than 99% pure.

### BRIEF DESCRIPTION OF THE DRAWINGS

The invention now will be described in more detail with reference to the attached drawing figures, in which:

FIG. 1 shows a suitable structure for an optical device according to the fourth aspect of the invention.

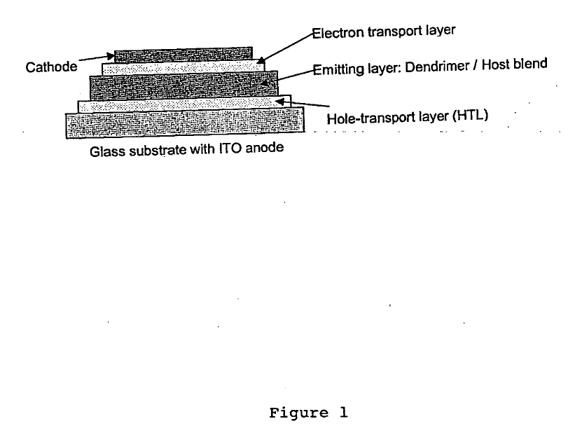

FIG. 2 shows the increased lifetime obtained by annealing (baking) the phosphorescent material.

### EXAMPLES

### Example 1

Onto a glass substrate carrying a layer of indium tin oxide was deposited a hole transporting layer divinyl-TPD, which was cross-linked by thermal treatment. A blend of green electrophosphorescent complex of formula (V) wherein R=2-ethylheptyloxy (as disclosed in WO 02/66552) and host material CBP in a ratio of complex (V): CBP of between 10:90 and 20:80 was deposited by spin coating from xylene solution onto the hole transporting layer. The substrate carrying the hole transporting layer and emissive layer was then heated on a hotplate at 125-130° C. for 10 minutes. An electron transporting layer of TPBI was deposited over the emissive layer by vacuum evaporation followed by evaporation of a thin layer of lithium fluoride and a capping layer of aluminium. The device was encapsulated using an airtight metal enclosure available from Saes Getters SpA.

### Comparative Example 1

A device was formed according to the method set out in Example 1 above except that the step of heating the emissive layer was omitted.

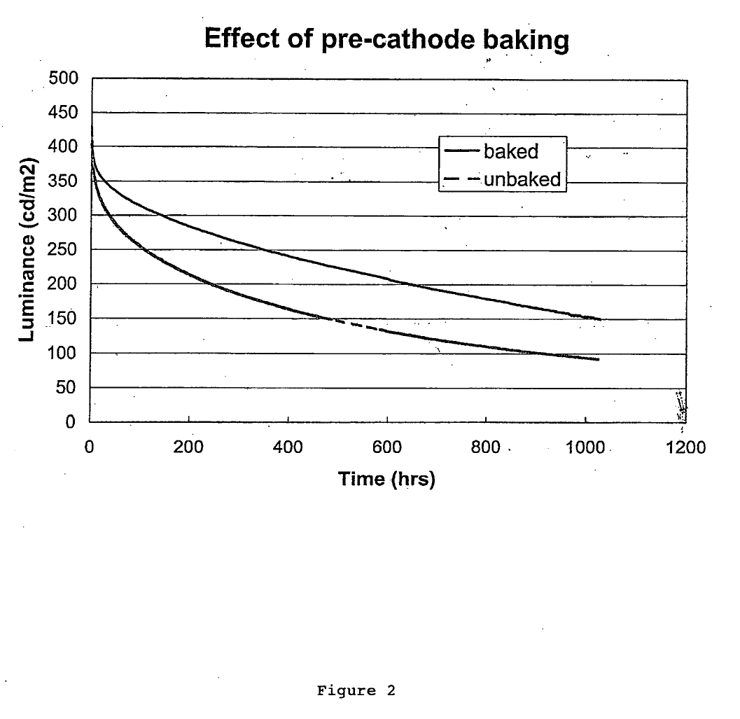

As can be seen from FIG. 2, the lifetime of the annealed device of Example 1 is approximately three times the lifetime of the device of Comparative Example 1.

1. A method of forming an emissive layer of an optical device, said method comprising the steps of:
(i) depositing a phosphorescent material to form a deposited layer; and
(ii) annealing the deposited layer to form an emissive layer.

2. A method according to claim 1, comprising depositing the phosphorescent material in step (i) by depositing a solution containing the phosphorescent material.

3. A method according to claim 1, comprising camming out step (ii) directly after deposition in step (i).

4. A method according to claim 1, wherein the phosphorescent material is part of a host material-dopant system, where the dopant comprises the phosphorescent material.

5. A method according to claim 4, wherein the host material and the phosphorescent material are present as separate materials, which are blended together.

6. A method according to claim 4, wherein the host material and the phosphorescent material are components of the same compound.

7. A method according to claim 6, wherein the compound is a polymer.

8. A method according to claim 1, comprising depositing the phosphorescent material directly onto a charge transport layer in step (i).

9. A method according to claim 8, wherein the charge transport layer comprises a hole transport layer.

10. A method according to claim 1, wherein the phosphorescent material comprises a metal complex.

11. A method according to claim 10, wherein the metal complex comprises a dendrimer with a metal as part of its core.

12. A method according to claim 11, wherein the dendrimer contains one or more at least partially conjugated organic dendrons.

13. A method of manufacturing an optical device, said method comprising forming an emissive layer by the method defined in claim 1.

14. A layer of an optical device obtained by the method defined in claim 1.

15. An optical device obtained by the method defined in claim 13.

16. An optical device according to claim 15, wherein the optical device comprises an organic light-emitting device.

17. An optical device according to claim 16, wherein the optical device comprises an electroluminescent device.

18. An optical device according to claim 16 comprising:
an anode;
a cathode; and
an emissive layer located between the anode and the cathode;
wherein the emissive layer comprises an annealed phosphorescent material.

19. An optical device according to claim 18, wherein the device contains a hole transport layer; located between the anode and the emissive layer.
